(19) United States
(12) Patent Application Publication
(10) Pub. No.: US 2011/0168954 A1
(43) Pub. Date: Jul. 14, 2011

(54) CARBON NANOTUBE BASED COMPOSITE SURFACE ENHANCED RAMAN SCATTERING (SERS) PROBE

(75) Inventor: Ramsey M. Stevens, Danville, CA (US)

(73) Assignee: Carbon Design Innovations, Inc., Burlingame, CA (US)

(21) Appl. No.: 12/959,283

(22) Filed: Dec. 2, 2010

Related U.S. Application Data
(60) Provisional application No. 61/266,090, filed on Dec. 2, 2009.

(51) Int. Cl. H01B 1/04; B29D 11/00; C23C 16/50; B05D 5/06; C09K 3/00; B82Y 30/00; B82Y 40/00

(52) U.S. Cl. 252/502; 264/1.27; 427/569; 427/579; 427/163.2; 252/182.32; 252/182.33; 977/742; 977/844; 977/954; 977/750; 977/752

(57) ABSTRACT

An electromagnetic and/or chemical enhancement which greatly enhances the Raman signal response for Surface Enhanced Raman is directed to molecular probe systems. Such molecular probe systems have many properties that make them ideal as probes for Scanning Probe Microscopy, Atomic Force Microscopy, and many other applications.

This application claims priority to U.S. Provisional Patent Application Serial Number 61/266,090, titled “Carbon Nanotube Based Composite SERS Probe,” filed Dec. 2, 2009, and incorporated herein by reference.

### BACKGROUND

Field of the Invention

The present invention relates to molecular probing, sensing and surface modification devices and systems and in particular without limitation relates to techniques that improve the Raman signal response for Surface Enhanced Raman.

### SUMMARY OF THE DESCRIPTION

Disclosed are techniques for fabrication and testing of a carbon nanotube (CNT)-based nano-electronic probe substrate for Surface Enhanced Raman Scattering (SERS) for molecular sensing and material modification applications. In some embodiments, the molecular probe system begins with an as-made CNT that is straightened or re-shaped and precision aligned along a desired axis. This probe is then transformed into a metal-coated (e.g., silver (Ag), gold (Au), platinum (Pt)), nano-engineered probe for maximized probe-molecule interaction. The probe can be further combined with scanning-probe microscopy, electrochemical, spectro-chemical, or other analytical methods for improving the analytical power of the approach. The technique utilizes high aspect ratio CNTs coated with dipole coupling metals with precise size and shape control for optimizing electric-field coupling for maximum SERS, near-field, and fluorescence response at nanoscale sites.

Other advantages and features will become apparent from the following description and claims. It should be understood that the description and specific examples are intended for purposes of illustration only and not intended to limit the scope of the present disclosure.

### BRIEF DESCRIPTION OF DRAWINGS

These and other objects, features and characteristics of the present invention will become more apparent to those skilled in the art from a study of the following detailed description in conjunction with the appended claims and drawings, all of which form a part of this specification. In the drawings:

FIG. 1 illustrates Ion Flux Molding (IFM) processing for nanoscale control over the morphology of carbon nanotubes (CNTs).

FIG. 2 provides a chart comparing how the material properties of a CNT can enhance Surface Enhanced Raman Scattering (SERS) response.

FIG. 3 illustrates an IFM method for fabricating CNTs.

FIG. 4 illustrates platinum (Pt), gold (Au), and silver (Ag)-coated CNT based probes that are fabricated in a variety of nanoscale shapes.

FIG. 5 depicts SERS spectra of R6G molecules on Ag-coated CNT.

FIG. 6 illustrates a Nanostructured Raman Sensor Array (NRSA), which is a product of a highly versatile, nanoengineered array of vertically-aligned, metal-coated carbon nanotubes.

### DETAILED DESCRIPTION OF THE INVENTION

Various examples of the invention will now be described. The following description provides specific details for a thorough understanding and enabling description of these examples. One skilled in the relevant art will understand, however, that the invention may be practiced without many of these details. Likewise, one skilled in the relevant art will also understand that the invention can include many other obvious features not described in detail herein. Additionally, some well-known structures or functions may not be shown or described in detail below, so as to avoid unnecessarily obscuring the relevant description.

The terminology used below is to be interpreted in its broadest reasonable manner, even though it is being used in conjunction with a detailed description of certain specific examples of the invention. Indeed, certain terms may even be emphasized below; however, any terminology intended to be interpreted in any restricted manner will be overtly and specifically defined as such in this Detailed Description section.

The techniques described herein generally entail employing carbon nanotube (CNT) nanomanufacturing techniques to fabricate a CNT-based enhanced Raman spectroscopy molecular sensor probe and molecular detection system. Several suitable CNT nanomanufacturing techniques are described in detail in U.S. Pat. No. 7,628,972, issued on Dec. 8, 2009, entitled “NANOSTRUCTURE DEVICES AND FABRICATION METHOD”, U.S. patent application No. 12/606,143, filed Oct. 26, 2009, entitled “ NANOSTRUCTURE DEVICES AND FABRICATION METHOD”, U.S. Pat. No. 7,601,650, issued on Oct. 13, 2009, entitled “CARBON NANOTUBE DEVICE AND PROCESS FOR MANUFACTURING SAME”, U.S. patent application No. 12/548,400, filed Aug. 26, 2009, entitled “CARBON NANOTUBE DEVICE AND PROCESS FOR MANUFACTURING SAME”, U.S. patent application No. 11/786,492, filed Apr. 11, 2007, entitled “CARBON NANOTUBE SIGNAL MODULATOR AND PHOTONIC TRANSMISSION DEVICE” which are all incorporated by reference in their entireties. According to one embodiment, the molecular probe system starts with a reshaped (straightened and aligned) CNT-base probe structure that is then transformed into a silver (Ag), gold (Au) or platinum (Pt)-coated nanoengineered composite SERS probe. This probe is the missing element remaining to establish the more widespread use of the powerful combination of Scanning Probe Microscopies (SPM) with molecular sensing spectroscopic methods for improvement of instrumentation for nanotechnology. Such a probe and probing system represents the use of a nanoscale CNT material and a nanomanufacturing procedure exemplifying techniques for the nanomanufacturing of CNTs, and commercial applications of CNTs resulting in creation of a functional Raman-based molecular nanosensor probe device. The device uses high aspect ratio CNTs, dipole coupling materials (e.g., Ag, Au, Pt) polarization effects (one-dimensional nanoantenna), wavelength coupling length effects with precise size and shape control incorporated above to optimize enhancement of the nanoengineered probe structure.

The nature of the described device and the Coulomb interaction between valence electrons in metal surfaces yields collective oscillations called plasmons and aspects of these collective excitations concentrates light in subwavelength structures. Surface plasmons and polaritons play a key role in a wide spectrum of science, ranging from physics and materials science to biology. Collective electronic excitations at metal surfaces serve as the basis for the design, fabrication, and characterization of the described device and serves as the basis for subwavelength waveguide components, plasmonic modulators and switches, near field microscopy probes, SERS substrates and TERS probes.

Surface Enhanced Raman Scattering (SERS) and the related Tip Enhanced Ramen Spectroscopy (TERS) are becoming increasingly more widely applicable. SERS as employed in the described device can be applied to the study of biomolecules and proteins including cancer gene detection, spectroscopy of living cells and single protein and DNA detection. Some of the Non-biological applications of the described device include but are not limited to single molecule detection, spectroscopy of dyes in nanocrystals and SERS Stokes/anti-Stokes spectroscopy in macromolecules like carbon nanotubes. SERS is a Raman Spectroscopic (RS) technique, which under resonant, collective oscillation conditions greatly enhances the Raman signal from a Raman-active analyte molecule that has been adsorbed onto a surface. The increased Raman signal is due to surface effects that lead to the electromagnetic (EM) enhancement and the chemical enhancement (CE) mechanisms. Increases in the intensity of Raman signal have been regularly observed on the order of 10⁴-10⁶, and can be as high as 10⁸ and 10¹⁴ for some systems. Raman Spectroscopy (RS) identifies structural information of an analyte with a high degree of selectivity.

The importance of SERS is that it greatly increases sensitivity and TERS adds localization, extending Raman Spectroscopy (RS) to a wider variety of interfacial systems including in-situ and ambient analysis of electrochemical, catalytic, biological, and organic systems. SERS/TERS can be conducted under ambient conditions not requiring a special environment. Also, the combination of SERS, which has a broad wave number range, and a highly selective surface that is highly sensitive, and TERS, which adds greater localization, creates the potential for direct molecular identification at the nanometer scale. Greater elucidation of the SERS phenomena is a result of applicant's extensive experimentation and theoretical studies of roughened metallic surfaces, metal nanoparticle and nanorod colloids and other configurations. Additionally, TERS combines SERS phenomena with Atomic Force Microscopy (AFM) and shows that similar Raman enhancement can result from a metallized high aspect ratio probe. There is extensive industry expertise processing silicon and fabricating silicon AFM cantilever and probe structures, but the techniques become increasingly more complicated as the structures approach the nanoscale and limitations in shape and dimension predominate making CNT-based probes more advantageous. The main challenge that this innovation overcomes is reproducible mass production of nanoengineered SERS substrates and TERS probes, probe arrays, and probe tips. This development is found in the present teaching.

Improving the mismatch between light and nanoscale objects is fundamental to the understanding and use of Raman enhancement methods. However, the CNT processing technology described herein offers advantages over other potential nanofabrication options by controllably and reproducibly fabricating Raman-active structures with nanoengineered signal enhancing properties significantly increasing the advantageous aspects of the device including the accessibility of ultra sensitive molecular detection for a wide range of applications.

Surface Enhanced Raman Scattering (SERS) effect is dependent on the conductive properties of nanoscale features. Multi-walled carbon nanotubes (MWCNTs) have been shown to have remarkable material properties and have dimensions and properties appropriate for electromagnetic interaction. However, working with CNTs and reliably making commercial devices from CNTs has proven difficult until Ion Flux Molding (IFM) processing techniques 10 (described herein and in the cross-referenced applications indicated above) allowed the CNT to be reformed from its random native shape 12 and orientation into a straight CNT 14 that is perfectly set to any angle providing a means to reproducibly make a nanoscale probe device platform and even probe arrays.

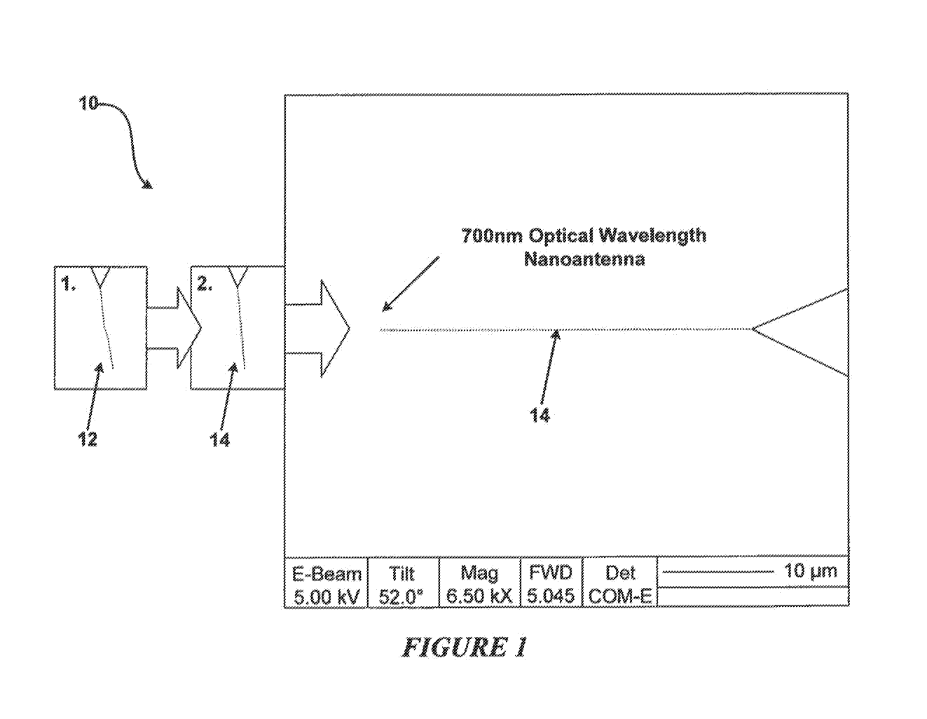

To this extent, refer to FIG. 1, which illustrates an IFM processing method 10 for nanoscale control over the morphology of the CNTs. In accordance to one embodiment, a carbon nanotube 12 having a curvature and a lack of proper angular alignment can be straightened into a desired configuration 14 with IFM processing. Through the exposure of the carbon nanotube to an ion beam, the nanotube probe can be straightened or bent in the direction from which an ion beam has been directed.

Ion Flux Molding (IFM) processing represents a technique for the fabrication of CNT-based devices by way of controlling the matter of a CNT at the submicroscopic scale in a systematic and reproducible fashion. The CNT probe structures described herein comprise an IFM-processed CNT at the core of a multilayered composite structure that can include metallized and/or insulated portions. By starting with a CNT at the heart of the composite probe structure the CNT provides a base scaffold upon which a more complex composite material may be assembled to match desired SERS effects. Suitable CNTs include but are not limited to those providing an approximately 25 nm diameter base nanostructure with lengths ranging from nanometers to microns and Au, Ag, and Pt coatings of varying thickness and shape.

In one embodiment, the probe resulting from the techniques described herein is an example of the application of an active nanostructure, combining photonic, chemical, and biological effects to a wide range of potential commercial products. This also provides the basis for a SERS/TERS individual “lightning rod” probe in scanning probe applications or in an array of probes on a substrate and could be applied to anything from laboratory instrumentation in the life sciences to handheld detectors and medical diagnostic devices. The single probe technology described herein can be extended into fabricating arrays of probes. Probes or arrays of probes can also be used in conjunction with a Scanning Probe Microscopy (SPM) platform for “hot spot” creation between the scanning and a second probe or probes. The technology has commercial applications ranging from water-quality monitoring and medical diagnostic devices to detection of explosives or chemical warfare agents. The high aspect ratio of the CNT and the capability to control the material properties, size and shape of the probe provides for potentially higher sensitivity, greater specificity and wider applicability and would represent commercial products based on a high performance, nanoengineered CNT SERS probe substrate.

Prior art development of nanoscale materials for Raman enhancement has been divided into general fields of research: nanoparticle dispersions and silicon processing of nanoscale structures including AFM cantilever probes. Chemistry techniques leading to nanoparticle and nanorod dispersions provide nanoscale control over material properties but are difficult to control for individual probe fabrication or in prescribed array spacing and dimensions and cannot be oriented normal to the surface in a probing configuration reliably. Lithographic processing of silicon generates a wide range of surface structures but individual nanoscale high aspect ratio structure fabrication remains a difficult challenge. Some of the best examples of nanoscale high aspect ratio structures can be found as AFM probes. Industry leading probe suppliers offer a wide range of probe types, revealing the potential technological starting points for development of an individual TERS probe structure. Standard AFM probes are typically pyramidal in shape and have moderate aspect ratios. Sharper AFM probes require further processing and are still only approximately 5:1 aspect ratios.

Metallized CNT-based nanoantenna structures have the highest aspect ratios and the potential to optimally provide optical fields that are confined to spatial scales below the diffraction limit. CNT-based metallized nanoantennas provide a platform to fabricate optimized Raman enhancing sensor devices and commercial products that exploit the interaction between electromagnetic fields and nanoscale objects. CNTs fabricated into functional antenna forms demonstrate photonic properties and antenna efficiencies comparable to predicted theoretical values. Further details of these photonic properties are explained in detail in U.S. patent application No. 11/786,492, filed Apr. 11, 2007, entitled “CARBON NANOTUBE SIGNAL MODULATOR AND PHOTONIC TRANSMISSION DEVICE”, which is incorporated in its entirety herein. Measured polarization is dependent upon the orientation of the CNT and IFM, proved capable of reproducibly orienting the CNT with precise right angles with length scales in the visible wavelength range. Additionally, metallized CNT-based nanostructures have the potential to improve the mismatch between light and a nanoscale probe or antenna.

Experimental results show that the local intensity enhancement factor relative to that for an incident diffraction-limited beam shows a strong dependence on polarization. Theoretical predictions for TERS probes define the tip shape, volume, surface material and thickness, incident beam angle, wavelength and polarization as the dominant factors affecting enhancement.

The dominant factors for tip shape are cone angle and tip radius. Plasmon enhancement of the Raman signal can be as high as 10¹⁴ in particular spots or clusters of Ag particles called “hot spots” exhibiting a complicated dependence on factors including the size, aspect ratio, spacing between particles, and clustering effects.

Electromagnetic enhancement factors for TERS probes have been reported on the order of 10²-10⁴ and precise control of tip properties may account for some of the difference between SERS and TERS. In TERS, a tip is used to enhance the Raman signal at a very localized region of the sample within a larger area that is being illuminated with laser light. This configuration is similar to a “rough” feature on a bulk substrate.

The aspect ratio of SERS/TERS structures plays an important role in Raman enhancement. Currently there are existing strategies utilizing colloid nanopartical dispersions or preexisting silicon lithographic structures that have generated promising data in laboratory settings. However, the CNT fabrication techniques described herein, combined with traditional silicon processing, offers a unique opportunity to directly fabricate a nanoscale probe structure with controlled material properties onto a desired substrate with the potential for commercial production volumes. The metallized CNT-based probe structures described herein created using IFM have an advantage in controllably fabricating high aspect ratio nanostructures. Controlled probe fabrication can lead to multiple novel applications such as intracellular single molecule detection or nanoscale defect analysis in semiconductor metrology and extrapolation of probe technology to arrays expands applicability further.

Almost all Single Molecule Surfaced Enhanced Raman Scattering (SMSERS) observations with nominal enhancement factors of 10¹³ or greater have been with resonant Raman scatterers showing an increased intensity over nonresonant molecules by a factor of 10⁴. Silver (Ag) has been widely reported associated with SERS phenomena along with gold (Au) and copper (Cu) and with evidence observed for platinum (Pt) and rhodium (Rh) as well. Continuum electrodynamics studies predict the enhancement factor for a nonresonant molecule on a single silver nanoparticle, when optimized for size and shape, is approximately 10⁵. Predictions can range as high as Eₘₐₓ=10¹⁰-10¹¹ for dimers of silver with nonresonant molecules. Eₘₐₓ values of 10⁹ and even 10¹³ have been predicted for increasingly more precisely engineered structures and geometries designed to take advantage of both the short range interactions associated with a dimer junction structure and long range electrodynamic interactions.

The enhancements have been shown to be the result of two separate phenomena: the electromagnetic (EM) and the chemical enhancement (CE) mechanisms. The EM enhancement factors cannot be completely extricated from the CE factors.

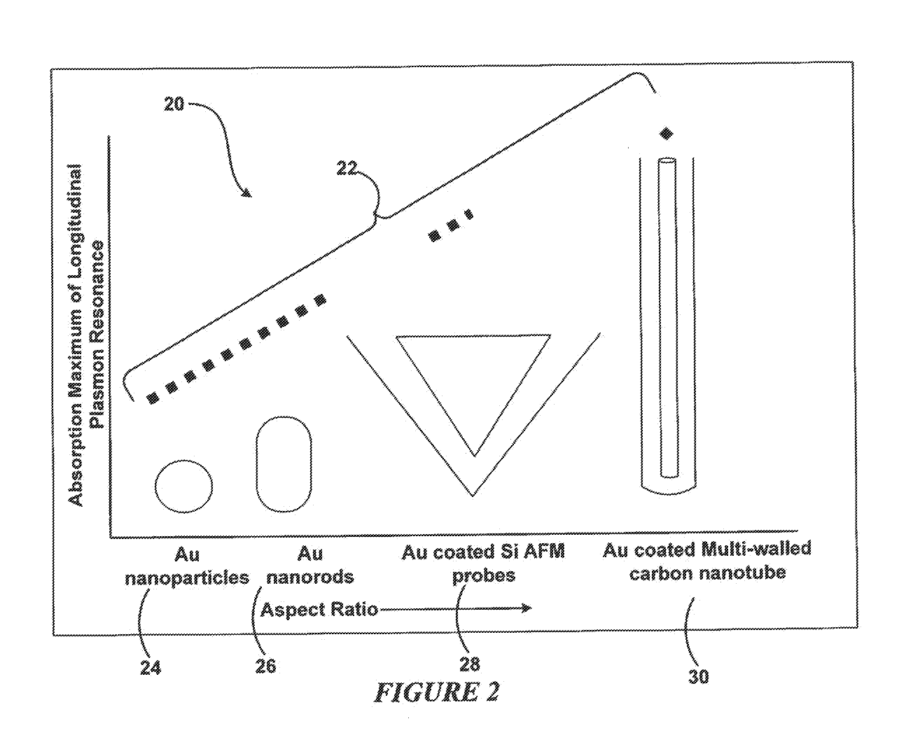

Computational electrodynamics studies of extinction and scattering spectra show that the EM enhancement factors of metal nanoparticles depend on their size, shape, arrangement, and dielectric environment, as shown in the illustration depicted in FIG. 2. FIG. 2 illustrates a chart 20 representing how material properties and shape (e.g.; diameter, aspect ratio) can affect the local electric field, thereby enhancing the SERS-response. The y-axis represents the maximum absorption of the longitudinal Plasmon resonance and the x-axis represents a scale of increasing aspect ratio. For each corresponding aspect ratio and/or shape, the datapoint(s) 22 represent estimated corresponding maximum absorption. In an exemplary embodiment, the maximum absorption of a nanoparticle enhanced with gold 24 is relatively lower than a nanorod enhanced with gold 26. As another example, the maximum absorption of a Au-coated Silicon AFM probe 28 is lower than a Au-coated Multi-Walled CNT 30. As such, the FIG. 2 depicts an estimated dependence of the SERS-enhancement on the aspect ratio of the nanoscope.

SERS studies using colloidal aggregates of nanoparticles and nanorods can be compared with TERS applications and Atomic Force Microscopy (AFM)-probe based enhancements, revealing that for a given metal, polarization, wavelength, incident angle, and target molecule; aspect ratio, size, and shape become the dominant factors. Polarization, wavelength, and incident angle are determined instrumentally and therefore precise control over the aspect ratio, size, and shape of nanoscale metallized nanostructures becomes paramount. Potentially, more complex core and shell geometries could also be fabricated and further play an enhancing role. Multi-layer core-shell geometries include insulating, semiconducting, or conductive materials that may improve the electromagnetic response. Example materials that can be incorporated into the multi-layers include, but are not limited to, metals, polymers, and silicon dioxide. Long-range electromagnetic interactions as well as two-dimensional and three-dimensional spatial relationships for isolated nanostructures and junctions between nanostructures all can be optimized in various embodiments. Electromagnetic enhancements at both the incident and stokes-shifted wavelengths can be achieved by theory-driven experimentation and optimization of the novel Raman nanostructure probes and array platforms in some embodiments.

Fabrication of Carbon Nanotube-based Composite SERS Active Probe

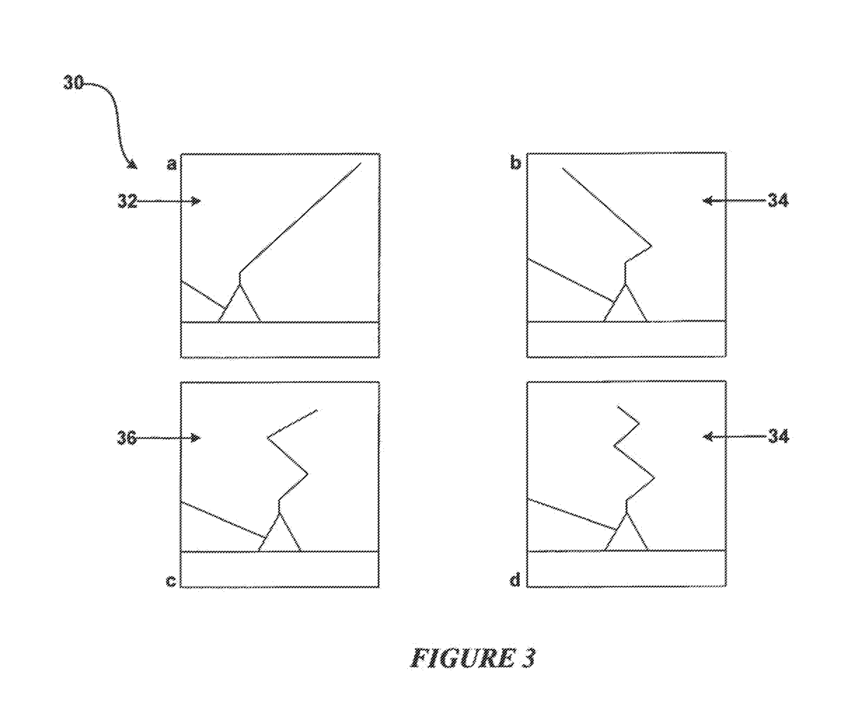

Carbon nanotubes (CNTs), carbon nanofibers, graphene, and other nanomaterials serve as the conductive, high aspect ratio nanostructure template upon which insulating, semiconducting, and/or conductive materials can be incorporated to create highly-functional, Raman-enhancing structures. The Ion Flux Molding (IFM) processing technique allows for fabrication of precise nanoscale CNT based devices. CNTs formed in thermal chemical vapor deposition (CVD) exhibit native curvature and grow in random directions. IFM processing molds the CNT into a functional device. IFM processing further provides CNT Atomic Force Microscopy (AFM) probes to the AFM consumables market. See, for example, FIG. 3, illustrating the use of IFM technology.

FIG. 3 shows the processing technique of IFM which allows for the fabrication of an enhanced probe with a CNT base in a desired configuration 30. According to one embodiment, FIG. 3(a) shows a CNT probe with a single sharp bend 32. Similarly, FIG. 3(b) shows a CNT with two sharp bends 34,

FIG. 3(c) shows a CNT with three sharp bends 36, and FIG. 3(d) shows a CNT with four sharp bends 38. Each of these sharp bends operates as a node for defining electromagnetic phenomena associated with the CNT. Such electromagnetic phenomenon, as understood by a skilled person in the art, enables the CNT to be used for a specified signal modification, enhancement, transmission, and modulation.

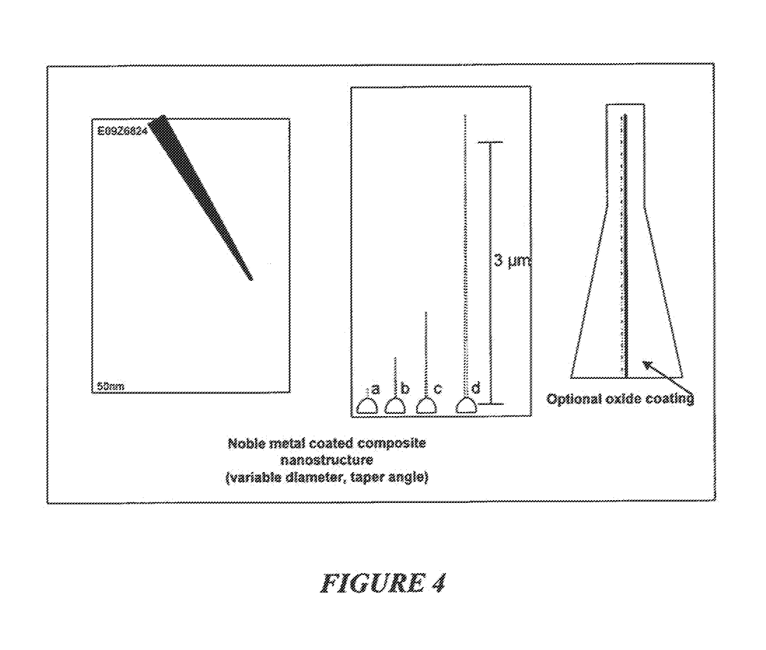

FIG. 4 further illustrates different shapes and compositions of CNT fabrication. In one embodiment, a composite nanostructure coated with a noble metal (e.g., Pt, Au, Ag) can be fabricated in a variety of nanoscale shapes. For example, the CNT can consist of a variable diameter or a tapered angle. Similarly, the nanostructure can include an optional oxide coating.

In one embodiment, a thin layer may also be added to the CNT to improve adhesion between the CNT and a material. The adhesion of gold, for example, is known to be weak on many different materials. The addition of a thin adhesion layer, such as titanium, which is sandwiched between the CNT and the gold, may be employed to minimize this problem. The method of adhering additional/other materials to the CNT for improved adhesion between the materials can be through a chemical reaction, mechanical energy, heat, ion or electron bombardment or other methods.

Formation of the composite structure from the base CNT provides the versatility to sequentially insulate and/or metallize the CNT, creating a wide range of nanoscale shapes, dimensions and properties. Using IFM, CNTs can be fabricated into a vertically-aligned or horizontally-aligned CNT structure, or the CNT can be set at any angle that most strongly interacts with the incident photons in a given instrumental layout.

Measurement of Electromagnetic Enhancement Factors for Carbon Nanotube-based Composite Probes

The enhancement of the electric field at metal-dielectric interfaces induced by illumination at optical frequencies is crucial for Surface Enhanced Raman Scattering (SERS), and has enabled the detection of single molecules. Metal dielectric interfaces support surface electromagnetic waves known as surface plasmon polaritons. These optical waves are essentially trapped at the interface because of their interaction with the free electrons of the metal, leading to highly-confined electromagnetic fields at the interface. Concentrating light in this way leads to an electric field enhancement, which can be used to boost nonlinear phenomena such as SERS.

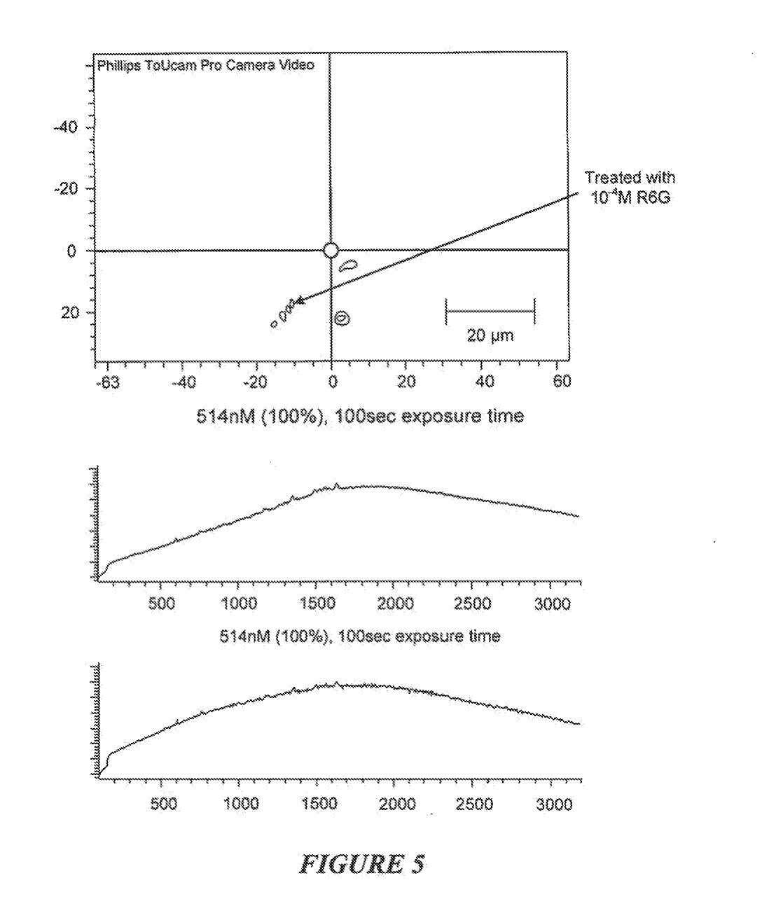

To this regard, FIG. 5 illustrates SERS response of a silver-coated CNT structure treated with 10⁻⁴M R6G, using 514 nm laser excitation with a collection times of 10 and 100 seconds.

Atomic Force Microscopy (AFM) has played a role analyzing the topography of surfaces but it has also played a well-known role in highlighting Raman enhancement factors in TERS. In TERS, a metallized sharp-tipped scanning probe is raster-scanned over a sample surface and electromagnetic (EM) enhancement factors from the sharp tip increases the Raman signal in a similar fashion to an isolated “rough” nanostructure as in the SERS phenomena. According to one embodiment, the use of a probe on a Scanning Probe Microscopy (SPM) platform and an array of the CNT probes on a substrate results in one engineered nanostructure “in-hand” and an array of the same, similar, or complimentary nanostructures on a controlled surface and the potential to controllably create a “hot spot” between the two or more nanostructures. Using an SPM platform, the single probe can controllably be brought into precise proximity and relation to any of the nanostructures or group configuration of nanostructures. Optimal dimensions, physical and chemical properties, and spatial relationships between neighboring nanostructures can be sought through theoretical predictions and experiments to enhance the incident and Stokes-shifted wavelengths. The near field region in the forward direction from a nanoantenna creates a “hot spot” that arises from the polarization and EM field enhancement from the nanoantenna. Advanced nanoantenna geometries using nanomaterial processing capabilities, combined with theory-led SPM experimentation makes this platform a powerful tool as an advanced SERS/TERS substrate.

Embodiments Utilizing Raman Active Probes:

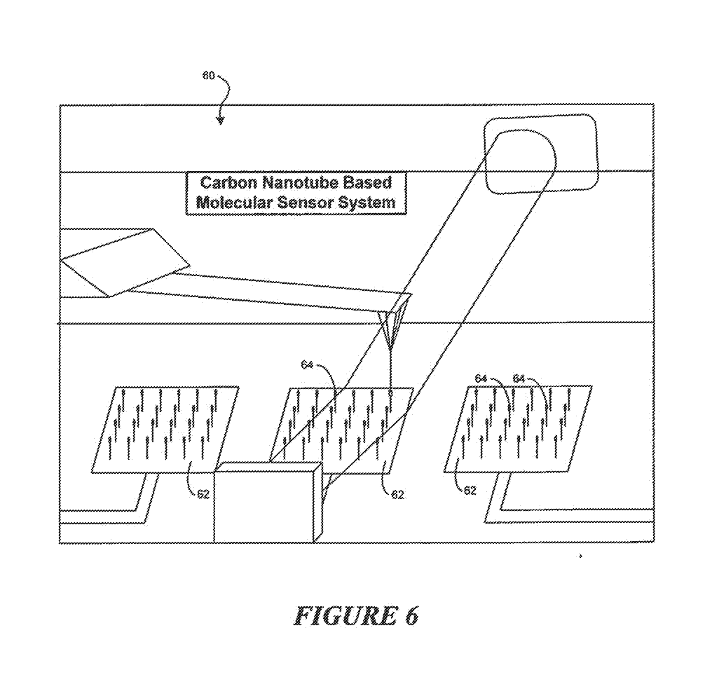

The single probe technology can be extended to fabrication of a CNT-based Nanostructured Raman Sensor Array (NRSA) of varying density and composition. These arrays provide a further opportunity to integrate CNT fabrication with conventional silicon lithography, leading to microdevices with precise nanoscale shape and aspect ratio control. Refer, for example, to FIG. 6, illustrating a carbon nanotube based molecular sensor system 60 consisting of a NRSA with highly-versatile nanoengineered arrays of vertically aligned metal-coated carbon nanotubes. Each array 62 consists of a plurality of CNT devices 64 formed on a substrate. Those skilled in the art will readily extrapolate from the description how to fabricate the NRSA. The CNTs may be formed in any other arrangement as desired by the application or may be broken up into smaller segments of CNT devices. The NSRA may be combined with material and liquid handling capabilities or other combinations or improvements.

In the above illustration, the inter-carbon nanotube distance can range from nanometers to microns. The length of exposed CNT can range from 1 nm to 10 μm with the CNT diameter ranging from 1 nm to 40 nm. Using thin film and electrochemical deposition techniques or other techniques, the CNT can be controllably metallized and or insulated modifying the nanostructure's Raman properties. The NRSA allows for process control over inter-nanostructure distances, nanostructure size, and aspect ratio maximizing the EM contribution to the Raman enhancement and yielding a highly functional SERS substrate. The NRSA achieves Eₘₐₓ per unit area and long-range EM interaction spacing within the same nanoengineered substrate. The NRSA substrate, combined with the single Raman enhanced probe, achieves Eₘₐₓ per unit volume by use of a nanoengineered substrate in conjunction with an optimized TERS probe. These probe and array properties and dimensions and the materials and processes involved make the combined Raman enhancing probe and NRSA substrate a powerful sensor system.

Other Commercial Embodiments

The same technology used to shape the Raman probes also can be applied to arrays of CNTs. Combining the single molecule detection capability of the proposed improved SERS AFM probe with an array of aligned CNT structures opens up a wide variety of potential inexpensive single molecule detection devices. One potential goal would be a device equivalent to a computer hard drive with the readout head consisting of the enhanced Raman CNT SERS probe, with a “compact disc (CD)” consisting of aligned CNT structures, each chemically altered to selectively adsorb or react with targeted analytes. The readout probe could very rapidly address each individual CNT structure to determine the presence of a particular analyte on a specific CNT within the array. The “CD” could be a tiny mobile film or plate, and used for a wide variety of purposes. An example includes using the “CD” as a monitor badge for chemical or biological exposures or an explosive residue detector by reading the swab of a surface. Another example is using the “CD” as a medical diagnostic device or bioassay kit. The “CD” could then be inserted into the Raman readout device.

The enhanced response in a localized region can be used for purposes other than sensing. The enhancement mechanism can be used for controllably modifying (chemically or otherwise) the surface of a material in a localized region. The technology and methods described herein can be further realized in useful functions, processes, or techniques such as microlithography or nanolithography.

A Raman TERS readout device is another embodiment that allows single molecule detection on each CNT structure. Such a CNT array device with a TERS readout detector would offer a tremendously flexible, yet extremely selective monitoring system. The CNT array TERS monitoring system would offer the following capabilities:

1) TERS readout provides localized highly sensitive molecular detection.

2) The array of CNTs gives a large number of densely-packed activated sites providing the opportunity to simultaneously screen for a wide variety of analytes.

3) The chemical activation of the CNT structures and active areas offer the opportunity to tailor the CNT monitor towards specific classes of compounds or hazards.

4) The Raman readout detector provides a final opportunity for specificity and characterization.

Unless the context clearly requires otherwise, throughout the description and the claims, the words “comprise,” “comprising,” and the like are to be construed in an inclusive sense (i.e., to say, in the sense of “including, but not limited to”), as opposed to an exclusive or exhaustive sense. As used herein, the terms “connected,” “coupled,” or any variant thereof means any connection or coupling, either direct or indirect, between two or more elements. Such a coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. While processes or blocks are presented in a given order in this application, alternative implementations may perform routines having steps performed in a different order, or employ systems having blocks in a different order. Some processes or blocks may be deleted, moved, added, subdivided, combined, and/or modified to provide alternative or subcombinations. Also, while processes or blocks are at times shown as being performed in series, these processes or blocks may instead be performed or implemented in parallel, or may be performed at different times. Further any specific numbers noted herein are only examples. It is understood that alternative implementations may employ differing values or ranges.

The various illustrations and teachings provided herein can also be applied to systems other than the system described above. The elements and acts of the various examples described above can be combined to provide further implementations of the invention.

Any patents and applications and other references noted above, including any that may be listed in accompanying filing papers, are incorporated herein by reference. Aspects of the invention can be modified, if necessary, to employ the systems, functions, and concepts included in such references to provide further implementations of the invention.

These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

1. A process for fabricating a carbon nanotube (CNT) device, the process comprising:
applying a material to the CNT device enabling an enhanced Raman signal.

2. The process of claim 1, wherein the CNT device is created using Ion Flux Molding (IFM).

3. The process of claim 1, wherein the material is formed using one or more of:
a second thermal chemical vapor deposition (CVD) process;
a physical vapor deposition process;
a CVD process;
a plasma-enhanced CVD process;
an electrochemical deposition process;
a molecular beam epitaxy process;
an electrochemical deposition process;
a spin casting process;
an evaporation process;
a reactive growth process; or
an atomic layer deposition process.

4. The process of claim 1, wherein the material is one or more of:
a silicon dioxide (SiO2) surface;
a doped silicon surface;
a compound silicon surface;
a polymer surface; or
a lithographic resist surface.

5. The process of claim 1, wherein an intermediate layer is applied to improve adhesion of the material to the CNT.

6. The process of claim 1, wherein the material includes an insulating material.

7. The process of claim 1, wherein the material includes a semiconducting material.

8. The process of claim 1, wherein the material includes a conductive material.

9. The process of claim 1, wherein the material includes at least one of the following:
silver;
gold;
platinum;
copper; or
rhodium.

10. The process of claim 1, wherein a property relating to the material can vary.

11. The process of claim 10, wherein the property is at least one of the following:
material property;
dielectric environment;
thickness;
volume;
arrangement;
size;
dimensions;
aspect ratio; or
shape.

12. The process of claim 1, wherein the material is selected for at least one of the following properties:
Surface Enhanced Raman Scattering (SERS) effect;
Tip Enhanced Raman Spectroscopy (TERS) effect;
plasmon enhancement;
electromagnetic enhancement;
chemical enhancement;
incident angle;
target molecule;
wavelength; or
polarization.

13. The process of claim 1, wherein the material is selected according to tip shape.

14. The process of claim 13, wherein one of the following properties factor into the tip shape:
cone angle; or
tip radius.

15. The process of claim 1, wherein the CNT device varies in at least one of the following properties:
geometry;
incident angle;
resonant excitation;
spatial orientation;
curvature;
surface area;
volume;
size;
dimensions;
aspect ratio; or
electromagnetic interaction.

16. The process of claim 15, wherein the electromagnetic interaction includes illumination at optical or other frequencies for electric field enhancement.

17. The process of claim 15, wherein the spatial orientation relates to neighboring nanostructures.

18. The process of claim 1, wherein the CNT device is a carbon nanofiber structure grown using a plasma enhanced chemical vapor deposition process.

19. The process of claim 1, wherein the CNT device is fabricated from silicon, silicon nitride, or silicon dioxide using lithographic processing.

20. The process of claim 1, wherein the CNT device has been modified by chemical reaction, material adherence decoration, or immersion of reactive or non-reactive species, for enhancement of probing interaction of other purpose.

21. The process of claim 1, wherein the CNT device is a single walled structure grown using a thermal chemical vapor deposition process.

22. The process of claim 1, wherein the CNT device is a multi-walled structure grown using a thermal chemical vapor deposition process.

23. The process of claim 1, wherein the CNT device is used in at least one of:
an atomic force microscope (AFM); or
a scanning probe microscope (SPM).

24. The process of claim 1, wherein the CNT device is an array of probes.

25. The process of claim 9, wherein the CNT device is an array of probes.

26. The process of claim 24, wherein a length of the CNT device is exposed, wherein said exposed length being defined by a specific application for said CNT device.

27. The process of claim 1, wherein the CNT device is suitable for use in at least one of:
a field emitter;
a sensor;
a lithographic device;
a logic device;
an electrical contact; or
an electrical interconnect.

28. The process of claim 24, wherein the CNT device is used in at least one of:
scanning probe microscope (SPM).

29. The process of claim 24, wherein the CNT device is suitable for use in at least one of:
a nanotube based antenna device;
nanotube tweezers;
a nanotube based manipulator device;
a nanotube based actuator; or
a nanotube based lever arm.

30. The process of claim 24, wherein the CNT device is suitable for use in at least one of:
a field emitter;
a sensor;
a lithographic device;
a logic device;
an electrical contact; or
an electrical interconnect.

31. A device comprising:
a carbon nanotube (CNT) which is a base of a nanostructure, wherein the nanostructure is comprised of more than one material.

32. The device of claim 31, wherein the CNT is created using Ion Flux Molding (IFM).

33. The device of claim 31, wherein the more than one material is formed using one or more of:
a second thermal chemical vapor deposition (CVD) process;
a physical vapor deposition process a CVD process;
a CVD process;
a plasma-enhanced CVD process;
an electrochemical deposition process
a spin casting process;
an evaporation process;
reactive growth process; or
an atomic layer deposition process.

34. The device of claim 31, wherein the more than one material includes one or more of:
an silicon dioxide (SiO2) surface;
a doped silicon surface;
a compound silicon surface;
a polymer surface; or
a lithographic resist surface.

35. The device of claim 31, wherein the more than one material is a material which increases adhesion to the CNT base or between layers.

36. The device of claim 31, wherein the more than one material includes an insulating material.

37. The device of claim 31, wherein the more than one material includes a semiconducting material.

38. The device of claim 31, wherein the more than one material includes a conductive material.

39. The device of claim 31, wherein the more than one material includes at least one of the following:
silver;
gold;
platinum;
copper; or
rhodium.

40. The device of claim 31, wherein a property relating to the more than one material can vary.

41. The device of claim 40, wherein the property is at least one of the following:
material property;
dielectric environment;
thickness;
volume;
arrangement;
size;
dimensions;
aspect ratio; or
shape.

42. The device of claim 31, wherein the more than one material is selected for at least one of the following properties:
Surface Enhanced Raman Scattering (SERS) effect;
Tip Enhanced Raman Spectroscopy (TERS) effect plasmon enhancement;
electromagnetic enhancement;
chemical enhancement;
incident angle;
target molecule;
wavelength; or
polarization.

43. The device of claim 31, wherein a property of the more than one material is selected according to tip shape.

44. The device of claim 43, wherein one of the following properties factor into the tip shape:
cone angle; or
tip radius.

45. The device of claim 31, wherein the CNT varies in at least one of the following properties:
geometry;
incident angle;
resonant excitation;
spatial orientation;
curvature;
surface area;
volume;
size;
dimensions;
aspect ratio; or
electromagnetic interaction.

46. The device of claim 45, wherein the electromagnetic interaction includes illumination at optical frequencies for electric field enhancement.

47. The device of claim 45, wherein the spatial orientation relates to neighboring nanostructures.

48. The device of claim 31, wherein the CNT is a carbon nanofiber structure grown using a plasma enhanced chemical vapor deposition process.

49. The device of claim 31, wherein the device is fabricated from silicon, silicon nitride, or silicon dioxide using lithographic processing.

50. The device of claim 31, wherein the CNT has been modified by chemical reaction, material adherence decoration, or immersion of reactive or non-reactive species, for enhancement of probing interaction of other purpose.

51. The device of claim 31, wherein the CNT is a single walled structure grown using a thermal chemical vapor deposition process.

52. The device of claim 31, wherein the CNT is a multi-walled structure grown using a thermal checmical vapor dposition process.

53. The device of claim 31, wherein the CNT is used in at least one of:
an atomic force microscope (AFM); or a scanning probe microscope (SPM).

54. The device of claim 31, wherein the CNT is an array of probes.

55. The device of claim 39, wherein the CNT is an array of probes.

56. The device of claim 54, wherein a length of the CNT is exposed, wherein said exposed length being defined by a specific application for said CNT device.

57. The device of claim 54, wherein the device is suitable for use in at least one of:
a field emitter;
a sensor;
a lithographic device;
a logic device;
an electrical contact; or
an electrical interconnect.

58. The device of claim 54, wherein the CNT is used in at least one of:
an atomic force microscope (AFM); or a scanning probe microscope (SPM).

59. The device of claim 31, wherein the CNT is suitable for use in at least one of:
a nanotube based antenna device;
nanotube tweezers;
a nanotube based manipulator device;
a nanotube based actuator; or
a nanotube based lever arm.

60. The device of claim 31, wherein the CNT is suitable for use in at least one of:
a field emitter;
a sensor;
a lithographic device;
a logic device;
an electrical contact; or
an electrical interconnect.

61. A method comprising:
fabricating a molecular sensor probe for an enhanced Raman signal, wherein the sensor probe is comprised of more than one material.

62. The method of claim 61, wherein the molecular sensor probe is created using Ion Flux Molding (IFM).

63. The method of claim 61, wherein the more than one material:
is grown;
is layered;
is deposited; or
is coupled to the CNT base.

64. The method of claim 61, wherein the more than one material includes a polymer.

65. The method of claim 61, wherein the more than one material includes silicon dioxide.

66. The method of claim 61, wherein an intermediate material improves adhesion of the more than one material to the CNT.

67. The method of claim 61, wherein the more than one material includes an insulating material.

68. The method of claim 61, wherein the more than one material includes a semiconducting material.

69. The method of claim 61, wherein the more than one material includes a conductive material.

70. The device of claim 61, wherein more than one material includes at least one of the following:
silver;
gold;
platinum;
copper; or
rhodium.

71. The method of claim 61, wherein a property relating to the more than one material can vary.

72. The method of claim 71, wherein the property is at least one of the following:
material property;
dielectric environment;
thickness;
volume;
arrangement;
size;
dimensions;
aspect ratio; or
shape.

73. The method of claim 61, wherein the material is selected for at least one of the following properties:
Surface Enhanced Raman Scattering (SERS) effect;
Tip Enhanced Raman Spectroscopy (TERS) effect plasmon enhancement;
electromagnetic enhancement;
chemical enhancement;
incident angle;
target molecule;
wavelength; or
polarization.

74. The method of claim 61, wherein the more than one material is selected according to tip shape.

75. The method of claim 74, wherein one of the following properties factor into the tip shape:
cone angle; or
tip radius.

76. The method of claim 61, wherein the molecular sensor probe is a carbon nanotube.

77. The method of claim 61, wherein the molecular sensor probe varies in at least one of the following properties:
geometry;
incident angle;
resonant excitation;
spatial orientation;
curvature;
surface area;
volume;
size;
dimensions;
aspect ratio; or
electromagnetic interaction.

78. The method of claim 77, herein the electromagnetic interaction includes illumination at optical frequencies for electric field enhancement.

79. The method of claim 77, wherein the spatial orientation relates to neighboring nanostructures.

80. The method of claim 61, wherein the molecular sensor probe is a carbon nanofiber structure grown using a plasma enhanced chemical vapor deposition process.

81. The method of claim 61, wherein the molecular sensor probe is fabricated from silicon, silicon nitride, or silicon dioxide using lithographic processing.

82. The method of claim 61, wherein the molecular sensor probe has been modified by chemical reaction, material adherence decoration, or immersion of reactive or non-reactive species, for enhancement of probing interaction of other purpose.

83. The method of claim 61, wherein the molecular sensor probe is a single walled structure grown using a thermal chemical vapor deposition process.

84. The method of claim 61, wherein the molecular sensor probe is a multi-walled structure grown using a thermal chemical vapor deposition process.

85. The method of claim 61, herein the molecular sensor probe is used in at least one of:
an atomic force microscope (AFM); or
a scanning probe microscope (SPM).

86. The method of claim 61, wherein the molecular sensor probe is an array of probes.

87. The method of claim 70 wherein the molecular sensor probe is an array of probes.

88. The method of claim 61, wherein a length of the molecular sensor probe is exposed, wherein said exposed length being defined by a specific application for said molecular sensor probe.

89. The method of claim 61, wherein the molecular sensor probe is suitable for use in at least one of:
a field emitter;
a sensor;
a lithographic device;
a logic device;
an electrical contact; or
an electrical interconnect.

90. The method of claim 86, wherein the molecular sensor probe is used in at least one of:
an atomic force microscope (AFM); or
a scanning probe microscope (SPM).

91. The method of claim 86, wherein the molecular sensor probe is suitable for use in at least one of:
a nanotube based antenna device;
nanotube tweezers;
a nanotube based manipulator device;
a nanotube based actuator; or
a nanotube based lever arm.

92. The method of claim 86, wherein the molecular sensor probe is suitable for use in at least one of:
a field emitter;
a sensor;
a lithographic device;
a logic device;
an electrical contact; or
an electrical interconnect.
